(19) United States
(12) Patent Application Publication
(10) Pub. No.: US 2014/0266291 A1
(43) Pub. Date: Sep. 18, 2014

(54) METHOD, DEVICE AND SYSTEM FOR AUTOMATIC DETECTION OF DEFECTS IN TSV VIAS

(71) Applicants: COMMISSARIAT A L'ENERGIE ATOMIQUE ET AUX ENE ALT, Paris (FR); Centre National de la Recherche Scientifique, Paris Cedex 16 (FR); Universite Montpellier 2 Sciences et Techniques, Montpellier (FR)

(72) Inventors: Yassine FKIH, Grenoble (FR); Pascal VIVET, Saint Paul de Varces (FR); Bruno ROUZEYRE, Montpellier (FR); Marie-Lise FLOTTES, Saint Georges d'Orques (FR); Giorgio DI NATALE, Mas de Londres (FR)

(73) Assignees: COMMISSARIAT A L'ENERGIE ATOMIQUE ET AUX ENE ALT, Paris (FR); Universite Montpellier 2 Sciences et Techniques, Montpellier (FR); Centre National de la Recherche Scientifique, Paris Cedex 16 (FR)

(21) Appl. No.: 14/212,621

(22) Filed: Mar. 14, 2014

(30) Foreign Application Priority Data
Mar. 15, 2013 (FR) 13 52306

(51) Int. Cl. G01R 31/26

(52) U.S. Cl. CPC G01R 31/2601
USPC 324/762.01

(57) ABSTRACT

A method for automatic detection of defects in TSV vias formed in a layer of semiconductor material, this detection taking place before stacking this layer with a plurality of other layers of semiconductor material for the design of a multilayer chip integrated circuit, comprising: measurement on each of said TSV vias of at least one parameter derived from an electrical characteristic of the TSV vias; detection of defects in said TSV vias according to a comparison of the parameters measured with at least one reference parameter, and calculation of said at least one reference parameter using the measured parameters. The parameter measured on each of the TSV vias comprises an oscillation frequency value derived from a capacitive characteristic of the TSV vias.

The present invention relates to a method for automatic detection of defects in TSV vias. It also relates to a detection device and system using this method.

### TECHNOLOGICAL BACKGROUND OF THE INVENTION

The invention applies more particularly to a method for automatic detection of defects in TSV vias formed in a layer of semiconductor material, this detection taking place before stacking this layer with a plurality of other layers of semiconductor material for the design of a multilayer chip integrated circuit, comprising:
measurement on each of said TSV vias of at least one parameter derived from an electrical characteristic of the TSV vias,
detection of defects in said TSV vias according to a comparison of the parameters measured with at least one reference parameter.

In order to achieve the performances and the diversification of the functions required in new electronic devices, miniaturization and grouping of electronic components of different types of technologies on the same chip prove to be necessary. The density of the interconnection networks on the same chip is in this way increased giving rise to undesired effects, such as the amplification of parasitic effects, the increase of interconnection times between components and the increase of energy dissipation, reducing the performances of the final electronic product. The stack of layers of semiconductor material of different types interconnected electrically using vertical connections through these layers helps address some of the problems mentioned above. This type of vertical connection through the layers is referred to as a TSV (derived from “Through Silicon Via”) via.

In order to validate the reliability of multilayer chip integrated circuits, reliability tests are carried out on each layer of semiconductor material of the circuit and in particular on the TSV vias which will perform the electrical interconnection between these layers. Furthermore, the tests on the TSV vias are performed at each stage of circuit production.

The detection of defects on the TSV vias in the first stages of circuit manufacture before stacking the layers facilitates the location and repair of the defects of these TSV vias. Nevertheless, testing the TSV vias before stacking involves constraints. In particular, the use of tester points in order to make direct contact with the TSV vias is technologically difficult, since the diameters of the TSV vias, of the order of 5 μm, are smaller than the diameters of standard tester points, of the order of 35 μm. Furthermore, the mechanical pressure applied by the tester points on the TSV vias should be controlled in order to avoid damaging the TSV vias. Finally, before the step for thinning the layer of semiconductor material, access to both ends of a TSV via is not possible, since the depth of a TSV via is generally approximately 80 μm whereas the layer of semiconductor material has a thickness of approximately 750 μm before thinning, thus limiting the types of tests that can be used.

In practice, so-called indirect test solutions are used. These solutions add to the integrated circuit, from the conception thereof, a test architecture for measuring certain electrical characteristics on each of the TSV vias formed in the layer of semiconductor material and automatically detecting certain defects in these TSV vias.

During the formation of certain TSV vias, two major types of manufacturing defects causing the modification of the electrical characteristics of the TSV vias may be detected:
“conductor defects”: poor filling of a TSV via or the presence of microvoids in the TSV via give rise to the appearance of cavities in the TSV via causing a variation of the capacitance and resistance thereof,
“insulator defects”: poor deposition of the insulator layer around a TSV via or dust deposited during the manufacture of the TSV via may give rise to a resistive connection between the TSV via and the layer of semiconductor material wherein it is formed, causing leakage currents through this TSV via.

### DESCRIPTION OF THE PRIOR ART

A number of TSV via test architectures have been proposed in recent years. The article by Chen et al, entitled “On-chip TSV testing for 3D IC before bonding using sense amplification”, published in Asian Test Symposium (ATS), pages 450-455, 2009, proposes the use of detection amplifiers. An inverter is connected to a

TSV via and thus makes it possible to charge the TSV via by means of the PMOS transistor of the inverter at the power supply voltage V_{DD} and discharge the TSV via by means the resistance of an NMOS transistor. The discharging time of the TSV via is measured and compared by a detection amplifier to a predefined reference, this amplifier comprising two inverters connected in series. The amplifier transistors are previously dimensioned with threshold voltages for determining the discharging time interval of the TSV vias without defects and generating an output signal on 1 bit. Nevertheless, this scheme involves limitations. On one hand, the resolution and precision of this solution are limited by the minimum discharging time that the detection amplifier can detect. Indeed, if the discharging time is too fast, the amplifier may not detect it correctly. On the other hand, the values of the reference threshold voltages for identifying the TSV vias without defects are set during the design of the circuit and the possible variations of the capacitances of the TSV vias and the threshold voltages of the transistors during the production of the circuit should be considered when choosing the discharging time interval of TSV vias without defects.

The article by Lou et al, entitled “Comparing Through-Silicon-Via (TSV) void/pinhole defect self-test methods”, published in Journal of Electronic Testing, Volume 28, Issue 1, pages 27-38, November 2011, describes and compares three methods for automatic detection of defects in TSV vias. The first method corresponds to that described above and uses detection amplifiers for measuring the variation of the discharging time of the TSV vias for detecting certain conductor defects and in some cases leakage currents through the insulator. The second method makes it possible to detect insulator defects by measuring the leakage current and comparing same to a reference value using a comparator. This method uses the same approach as the previous method, but replaces the NMOS transistor by a resistor of predefined value. The third method makes it possible to detect certain conductor defects by comparing the capacitance of the TSV via to a reference capacitance integrated in the circuit, the value of this capacitance corresponding to the expected value of an estimated capacitance of a TSV via without defects. The disadvantages of this final method in relation to the two others are the large surface area and high consumption of the test circuit used for making the measurements and the need to design reference capacitances of the order of one femtofarad. In the three cases described above, the test circuit output is connected to a digitization chain comprising multiplexers and flip-flop memories and outputting a pass/fail bit for each of the TSV vias tested.

All the methods for detecting defects in TSV vias described above compare parameters measured to predefined parameters set during circuit design, for example the discharging time, resistance or capacitance of a TSV via without defects. The precision of the tests performed in this way may be compromised by possible variations of the values of these predefined parameters during the circuit production process.

It may thus be sought to provide a method for automatic detection of defects in TSV vias suitable for overcoming at least some of the problems and constraints mentioned above.

### SUMMARY OF THE INVENTION

The invention thus relates to a method for automatic detection of defects in TSV vias formed in a layer of semiconductor material, this detection taking place before stacking this layer with a plurality of other layers of semiconductor material for the design of a multilayer chip integrated circuit, including:
measurement on each of said TSV vias of at least one parameter derived from an electrical characteristic of the TSV vias,
detection of defects in said TSV vias according to a comparison of the parameters measured with at least one reference parameter,
   further comprising a step for calculating said at least one reference parameter using the measured parameters.

In this way, by means of the invention, the reference parameter(s) are not set in absolute terms during circuit design, but calculated in relative terms using the parameters measured during the circuit reliability tests. As these parameters can be calculated at each stage of the circuit production process when measurements are made, the test is not altered by a possible variation of the values of the electrical characteristics of the TSV vias and transistors taking place during the various stages of the circuit production process. This is particularly true when some production parameters, for example, the temperature or the power supply voltage, may vary overall and thus affect the parameters measured.

Advantageously, said at least one parameter measured on each of the TSV vias includes an oscillation frequency value derived from a capacitive characteristic of the TSV vias.

Optionally, the calculation of said at least one reference parameter comprises:
the determination, based on the parameters measured, of an expected value of the parameter to be measured on each of said TSV vias, this expected value being considered to be characteristic of a TSV via without defects, and
the calculation of said at least one reference parameter by applying a predefined and programmable permitted deviation parameter relative to this expected value.

Also optionally, the measurement on each of said TSV vias of an oscillation frequency derived from a capacitive characteristic of the TSV vias includes the following steps:
connection of a set of ring oscillators to all the TSV vias formed in the layer of semiconductor material, each ring oscillator being connected to at least one TSV via,
sequential selection of each of said ring oscillators,
sequential measurement of an oscillation frequency of each ring oscillator selected.

Also optionally:
the expected value, annotated F_{MIN}, is the lowest of the oscillation frequencies measured,
the permitted deviation parameter, annotated TTT, is expressed as a percentage of the expected value, and
said at least one reference parameter, annotated F_{REF}, is a threshold frequency calculated as follows:

F_{REF}=F_{MIN}·(1+TTT),

defects being detected in said TSV vias once a measured oscillation frequency exceeds this threshold frequency.

Also optionally:
the expected value, annotated F_{MOY}, is the mean of the oscillation frequencies measured,
the permitted deviation parameter, annotated TTT, is expressed as a percentage of the expected value, and
said at least one reference parameter, annotated [F_{REF-INF}, F_{REF-SUP}], consists of the lower and upper limits of a frequency interval calculated as follows:

F_{REF-INF}=F_{MOY}·(1−TTT) and F_{REF-SUP}=F_{MOY}·(1+TTT),

defects being detected in said TSV vias once a measured oscillation frequency is outside this interval.

The invention also relates to a device for automatic detection of defects in TSV vias formed in a layer of semiconductor material, for a detection taking place before stacking this layer with a plurality of other layers of semiconductor material for the design of a multilayer chip integrated circuit, comprising:
means for measuring on each of said TSV vias at least one parameter derived from an electrical characteristic of the TSV vias,
means for detecting defects in said TSV vias according to a comparison of the parameters measured with at least one reference parameter, further comprising means for calculating said at least one reference parameter based on the parameters measured.

Advantageously, said at least one parameter measured on each of the TSV vias comprises an oscillation frequency value derived from a capacitive characteristic of the TSV vias.

Optionally, the measuring means include a set of ring oscillators connected to all the TSV vias formed in the layer of semiconductor material, each ring oscillator being connected to at least one TSV via.

Also optionally, the calculating means include:
a counter of a number of rising edges of an oscillation signal of a ring oscillator selected sequentially for a predefined and programmable counting time, for the sequential supply of an oscillation frequency value,
a computer of at least one expected value of the oscillation frequency to be measured on each of said ring oscillators, this expected value being considered to be characteristic of a ring oscillator connected to at least one TSV via without defects, and of at least one reference frequency by applying a predefined and programmable permitted deviation parameter relative to this expected value.

The invention also relates to a system for automatic detection of defects in TSV vias, comprising:
a detection device according to the invention, and
a module for controlling access, from an external tester, to the detection device according to the IEEE 1149.1 standard or JTAG standard.

### BRIEF DESCRIPTION OF THE DRAWINGS

The invention will be understood more clearly using the description hereinafter, given merely as an example and with reference to the appended drawings wherein:

FIG. 1 illustrates schematically the general structure of a system comprising a device for automatic detection of defects according to one possible embodiment of the invention,

FIG. 2 represents a sectional view of a layer of an integrated circuit comprising TSV vias with defects,

FIG. 3 represents the electrical diagram of measuring means of the detection device in FIG. 1, connected to the TSV vias of an integrated circuit,

FIG. 4 illustrates in detail the electrical diagram of a ring oscillator of the measuring means in FIG. 3,

FIG. 5 represents an electrical diagram of alternative measuring means to that represented in FIG. 3, according to one preferred embodiment,

FIG. 6 illustrates the successive steps of a detection method implemented by the detection device in FIG. 1 using the measuring means in FIG. 3 or FIG. 5.

### DESCRIPTION OF PREFERRED EMBODIMENTS

The system 10 for automatic detection of defects represented schematically in FIG. 1 comprises a device 12 for automatic detection of defects in TSV vias 14 formed in a layer of semiconductor material of a multilayer chip integrated circuit. Optionally, this detection system 10 comprises a module 16 for controlling possible access using an external tester 34, obviously outside the detection device 12, according to the IEEE 1149.1 standard, or JTAG (Joint Test Action Group) standard.

The device 12 for detecting defects comprises means 18 for measuring, on each of the TSV vias 14, parameters derived from an electrical characteristic of the TSV vias 14. These measuring means will be detailed with reference to FIGS. 3, 4 and 5. It further comprises means 20 for calculating one or a plurality of reference parameters in relative terms based on the parameters measured and means 22 for detecting defects in the TSV vias by comparing the parameters measured with the reference parameter(s) calculated. The calculation means 20 comprise more specifically a counter 24 and a computer 26. The operation of the counter 24, computer 26 and detection means 22 will be detailed with reference to FIGS. 4, 5 and 6.

The device 12 for detecting defects further comprises a finite-state machine 28 for starting same and transmitting the detection results. Moreover, this finite-state machine 28 supplies programmable predefined control signals and parameters required for controlling the measuring means 18, calculation means 20 and detection means 22.

The control module 16, described as a JTAG controller, is equipped with one or a plurality of JTAG registers 32 readable and writeable by a JTAG tester 34 external to the system 10 and using signals complying with the JTAG standard. This JTAG controller 16 has a JTAG instruction decoder 30 capable of interpreting such instructions stored in memory in the JTAG register(s) 32 thereof and generating instruction signals to the finite-state machine 28. It also has an interface 36 for receiving and transmitting defect detection results in the TSV vias 14, this interface 36 being configured to receive these results from the detection means 22 and to transmit same to the external JTAG tester 34.

FIG. 2 gives an example of TSV vias with defects, as can be found among the TSV vias 14 in FIG. 1. More specifically, it illustrates a sectional view of a layer of a multilayer chip integrated circuit comprising three vias TSV₁, TSV₂ and TSV₃, formed in a layer of semiconductor material 38 before thinning and stacking this layer with a plurality of further layers of semiconductor material. These TSV vias are surrounded by an insulating material 40A for insulating the TSV vias from the layer of semiconductor material 38. The upper end of each of these TSV vias is in contact with a metal track 42 suitable for example for connecting these vias TSV₁, TSV₂ and TSV₃ with one or a plurality of logic functions of this layer of semiconductor material 38. The lower end of the vias TSV₁, TSV₂ and TSV₃ is situated in the layer of semiconductor material 38 and does not lead to the outside since the layer of semiconductor material 38 is illustrated in this figure at a stage of integrated circuit production wherein it has not yet been thinned. It should further be noted that a layer of insulating material 40B may extend at the level of the upper end of the vias TSV₁, TSV₂ and TSV₃ between the layer of semiconductor material 38 and the metal track 42. Insulating material 40C may also be inserted between the conductors of the metal track 42. The insulator 40A surrounding the TSV vias, that 40B separating the layer of semiconductor material 38 from the metal track 42, and that 40C extending into the metal track 42 between the conductors thereof, may be the same insulator.

FIG. 2 further illustrates three types of defects liable to appear during the formation of a TSV via during the production process of an integrated circuit. Insufficient filling 44 of the via TSV, or the presence of a microvoid 46 in the via TSV₂ causes a reduction of the capacitance of the vias TSV₁ and TSV₂ in relation to the capacitance of a TSV via without defects. Dust 48 deposited around the via TSV₃ during the production process may cause leakage currents through this via.

FIG. 3 represents the electrical diagram of the measuring means 18 according to one possible embodiment of the invention. The measuring means 18 are directly connected to each (TSV₁, TSV₂, . . . , TSV_{N}) of the N TSV vias 14 formed in the layer of semiconductor material 38 of an integrated circuit and make it possible to measure parameters derived from an electrical characteristic of these TSV vias 14. The TSV vias 14 are further indirectly connected to the ground by a direct connection of the semiconductor material 38 to this ground. They are thus not electrically floating.

According to this embodiment of the invention, the measuring means 18 comprise a set {OSC₁, OSC₂, . . . , OSC_{J}} of ring oscillators, each connected to at least one via TSV₁ of the set of TSV vias 14. More specifically, in the example illustrated in FIG. 3, each ring oscillator is connected to a plurality of TSV vias, for example three: the ring oscillator OSC₁ is thus connected to the vias TSV₁, TSV₂ and TSV₃, the ring oscillator OSC₂ is connected to the vias TSV₄, TSV₅ and TSV₆, . . . and the ring oscillator OSC_{J} is connected to the vias TSV_{N-2}, TSV_{N-1}, and TSV_{N}.

The finite-state machine 28 is designed to control these measuring means 18 by sequentially selecting and applying each of the ring oscillators of the set {OSC₁, OSC₂, . . . , OSC_{J}}.

Any one of the ring oscillators in FIG. 3 is detailed in FIG. 4. This ring oscillator, annotated OSCⱼ, is connected to a plurality of vias TSV, for example three vias annotated TSViᵢ₋₁, TSVᵢ, TSVᵢ₊₁. Such a ring oscillator OSCⱼ consists of an odd number of “inverting” logic gates, or inverters 50, connected in a ring to each other generating an oscillating signal at the output of each logic gate characterized by a certain oscillation frequency.

Moreover, in the example of the ring oscillator illustrated in FIG. 4, an AND logic gate 52 receiving on an additional input a control signal C is intended to start up and shut down the ring oscillator OSCⱼ.

When the ring oscillator OSCⱼ starts oscillating, the value of the oscillation frequency of the oscillation signal varies with the number of TSV vias connected to the oscillator and with the capacitive characteristics of the TSV vias to which it is connected.

The inverters 50 of the ring oscillator OSCⱼ are positioned before and after each via TSVᵢ₋₁, TSVᵢ, TSVᵢ₊₁ for charging each TSV via on the rising edge of the oscillation signal and discharging on the falling edge of the oscillation signal. The charging and discharging times of each of the vias TSVᵢ₋₁, TSVᵢ, TSVᵢ₊₁ connected to the ring oscillator OSCⱼ vary according to the value of the capacitance of each TSV via. In this way, if the value of the capacitance of a TSV via decreases, the charging and discharging times of this TSV decrease causing a reduction in the duration of the oscillation period and consequently an increase in the frequency of the ring oscillator OSCⱼ.

By way of example and as mentioned above, insufficient filling 44 of any one of the vias TSV_{i-1, TSV}ᵢ, TSVᵢ₊₁ causes a reduction of the capacitance of this TSV via and the value of the oscillation frequency Fⱼ of the ring oscillator OSCⱼ connected to this via will be higher than that of a ring oscillator connected to TSV vias without defects.

The conductor defects in the TSV vias may thus be detected by measuring the values of the oscillation frequencies (F₁, F₂, . . . , F_{J}) of the ring oscillators OSC₁, OSC₂, . . . , OSC_{J} and by comparing same with a reference frequency F_{REF}.

As a reminder, the function of the TSV vias 14 in a multilayer integrated circuit is that of providing communication between two layers, one upper and the other lower, of the circuit. In this way, data D from any logic function 54 of the multilayer integrated circuit transit between the various layers of the circuit through the TSV vias 14, the logic function 54 being also connected to the TSV vias 14. The system 10 for automatic detection of defects is in turn added to the integrated circuit during the design thereof, the end purpose of this system 10 being that of automatically detecting the defects in TSV vias of the integrated circuit during the test stages during circuit production. Nevertheless, at the end of circuit production, the system 10 also remains integrated in the circuit, but it is no longer active and should not impede the transmission of data D between the logic function 54 and the TSV vias 14 during the operation of the circuit.

It is thus necessary to make a distinction between two different operating modes of the TSV vias 14: a functional mode, used for operating the integrated circuit, wherein the connection of the logic function 54 to the TSV vias 14 is activated so that the data D passes through the TSV vias; and a test mode, used for detecting defects in the TSV vias, wherein the connection of the ring oscillators OSC₁, OSC₂, . . . , OSC_{J} to the TSV vias 14 is activated so that they oscillate.

In order to isolate these two operating modes from each other, one possible solution well known to those skilled in the art consists of using inverters with three-state outputs. This type of inverter includes a control signal enabling same to switch from a valid output state, the output adopting a high or low value, to an invalid output state or high-impedance state wherein the output of the inverter has no influence on the rest of the circuit. Advantageously, the control signal supplying these inverters with three-state output is the control signal C intended to start up and shut down the ring oscillator OSCⱼ.

The ring oscillator OSCⱼ is thus more specifically equipped with inverters 50 with three-state outputs, the valid/invalid output state of these inverters 50 responding to the control signal C. On the other hand, inverters 58 with three-state outputs responding to the control signal C when inverted or C̅ are positioned in the path whereby the data D transit between the logic function 54 and the vias TSVᵢ₋₁, TSVᵢ, TSVᵢ₊₁. In this way, in the functional mode, the control signal C equals 0 and the output of the inverters 50 of the ring oscillator OSCⱼ switches to the high-impedance state disconnecting the oscillator from the rest of the circuit. At the same time, the outputs of the inverters 58 are in the valid state and the data D can flow through the vias TSVᵢ₋₁, TSVᵢ, TSVᵢ₊₁ between the upper and lower layers of the circuit. In test mode, the control signal C equals 1, consequently the outputs of the inverters 58 switch to the high-impedance state and the outputs of the inverters 50 become valid triggering the oscillation of the ring oscillator OSCⱼ and enabling testing of the vias TSVᵢ₋₁, TSVᵢ, TSVᵢ₊₁.

In order to measure the oscillation frequency of the ring oscillator selected by the finite-state machine 28, the counter 24 of the calculating means 20 is designed to count, for a predefined and programmable counting time T_{C}, a number of rising edges of the selected ring oscillator, for example OSCⱼ, and thus determines the oscillation frequency Fⱼ thereof. This counter 24 thus measures the value of an oscillation frequency dependent on the value of the capacitances of the TSV vias connected to the ring oscillator OSCⱼ. The value of this oscillation frequency is not constant and varies according to the charging and discharging time of the TSV vias 14.

During the production process of an integrated circuit, some production parameters, for example the temperature or the power supply voltage, may vary. It has been demonstrated that for the same capacitance value of the TSV vias, these variations affect the value of the oscillation frequency measured. In this way, from one production process to another, it is possible to have different oscillation frequency values for the same capacitance value, demonstrating that it is not desirable to have an absolute reference for these frequency values. On the other hand, relative variations of the oscillation frequencies measured in respect of each other for the same capacitance value are insensitive to variations in production parameters, demonstrating that it is advantageous to have a relative reference for these frequency values.

Finally, the value of the relative frequency variations is dependent on the variation in capacitance of the TSV vias and the number of TSV vias connected to each ring oscillator.

It has further been demonstrated that, the greater the number of TSV vias connected to a ring oscillator, the lower the significance of the relative frequency variation in relation to the variation of the capacitances thereof. Consequently, the best frequency variation measurement precision is obtained when a single TSV via is connected to a ring oscillator.

FIG. 5 is an alternative figure to FIG. 3 and illustrates the electrical diagram of the measuring means 18 in a preferred embodiment where a single TSV via is connected to each ring oscillator.

More specifically, each ring oscillator of the set {OSC₁, OSC₂, . . . , OSC_{J}} of ring oscillators is connected to a single TSV via of the set {TSV₁, TSV₂, . . . , TSV_{N}} of TSV vias 14. In this way, the ring oscillator OSC₁ is connected to the via TSV₁, the ring oscillator OSC₂ is connected to the via TSV₂, . . . and the ring oscillator OSC_{J} is connected to the via TSV_{N}, the number J of ring oscillators being, in this case, the same as the number N of TSV vias, N=J.

Each of these ring oscillators comprises two inverters positioned before and after the TSV via to which it is connected, for charging and discharging the TSV via, and a NAND logic gate controlled by the signal C, intended to start up and shut down the oscillator.

The computer 26 of the calculating means 20 is designed to calculate an expected value F_{TH} of the oscillation frequency of a ring oscillator based on the values of the oscillation frequencies (F₁, F₂, . . . , F_{J}) actually measured for each of the ring oscillators OSC₁, OSC₂, . . . , OSC_{J}, all these values coming from the counter 24. This expected value F_{TH} is considered to be characteristic of a ring oscillator connected to one or a plurality of TSV vias without defects. Furthermore, the computer 26 supplies at least one reference frequency F_{REF} by applying a predefined and programmable permitted deviation parameter TTT in relation to this expected value F_{TH}. The parameter TTT is for example expressed as a permitted percentage of variation in relation to the expected value F_{TH} of the oscillation frequency of a ring oscillator comprising TSV vias without defects. This value of the TTT parameter is dependent on the permitted variations of the capacitances of the TSV vias 14 and the number of TSV vias connected to each ring oscillator.

The detection means 22 detect whether in the circuit there is at least one TSV via with a defect by comparing the oscillation frequency values measured F₁, F₂, . . . F_{J} with said at least one reference frequency F_{REF}.

The detection method illustrated in FIG. 6 and implemented by the device 12 in FIG. 1 comprises a first measuring step 100, on each of the TSV vias 14, of at least one parameter derived from an electrical characteristic of the TSV vias. More specifically, in the example of the measuring means 18 in FIGS. 3, 4 and 5, the parameter measured on each of the TSV vias is a reference oscillation frequency value, dependent on a capacitive characteristic of this TSV via, of the ring connector connected to this TSV via.

More specifically, during a first substep 102 of the first step 100, the measuring means 18 comprising the set {OSC₁, OSC₂, . . . , OSC_{J}} of ring oscillators are connected to all the TSV vias formed in the layer of semiconductor material 38, each ring connector being connected to at least one TSV via (one via in the example in FIG. 5 or three vias in that in FIG. 3). The control C makes it possible to make this connection when starting up the ring oscillators while isolating the functional paths of the circuit.

During a second substep 104 of the first step 100, the finite-state machine 28 sequentially selects each of the ring oscillators OSC₁, OSC₂, . . . , OSC_{J} of the measuring means 18.

During a third substep 106 of the first step 100, the counter 24 of the calculating means 20 sequentially measures the oscillation frequency of each ring oscillator selected. In this way, after previously receiving from the measuring means 18 the oscillation signal of the ring oscillator selected, the counter 24 counts a number of rising edges of this oscillation signal during the predefined and programmable counting time T_{C} previously supplied to the counter 24 by the finite-state machine 28. Then, this counter 24 sequentially supplies the computer 26 with the oscillation frequency values of each ring oscillator selected.

The counting time T_{C} is chosen so as to prevent saturation of the counter 24 particularly for a maximum oscillation frequency of a ring oscillator. By way of example, if for a ring oscillator not charging any TSV the maximum oscillation frequency does not exceed the value of 2 GHz and the dimension of the counter 24 is set to 12 bit, the maximum value of the counting time will be 2

During a second step 108, the computer 26 of the calculating means 20 sequentially receives from the counter 24 the values F₁, F₂, . . . , F_{J} of the oscillation frequencies measured corresponding to the various ring oscillators OSC₁, OSC₂, . . . , OSC_{J} of the measuring means 18 and calculates, based on these frequencies, the expected value F_{TH} of the oscillation frequency of a ring oscillator connected to one or a plurality of TSV vias without defects and at least one reference frequency F_{REF} by applying the predefined and programmable permitted deviation parameter TTT in relation to this expected value.

According to a first possible embodiment, the expected value F_{TH} of the frequency of a ring oscillator connected to one or a plurality of TSV vias without defects, annotated F_{MIN}, is the lowest of the oscillation frequencies measured. In this case, the reference frequency F_{REF}, is a threshold frequency calculated by adding to the expected value F_{MIN}, a permitted frequency deviation, this frequency deviation being in turn the product of the permitted deviation parameter TTT defined above with the expected frequency F_{MIN}, according to the expression: F_{REF}=F_{MIN}*(1+TTT).

As a general rule, the value of the minimum frequency F_{MIN} is associated with the TSV vias having the highest capacitance and thus with the TSV vias formed without defects. Consequently, the reference frequency F_{REF} corresponds to TSV vias having a lower capacitance and represents the permitted deviation over the expected frequency F_{MIN} characteristic of an oscillator connected to TSV vias without defects. In this way, once a measured oscillation frequency exceeds this threshold frequency F_{REF}, it can be considered to correspond to one or more TSV vias formed with defects.

According to a second possible embodiment, the expected value F_{TH} of the frequency of a ring oscillator connected to one or a plurality of TSV vias without defects, annotated F_{MOY}, is the mean of the oscillation frequencies measured. In this case, the two reference frequencies, annotated [F_{REF-INF}, F_{REF-SUP}], consist of the lower and upper limits of a frequency interval calculated respectively as a subtraction and addition in relation to the expected frequency F_{MOY} of a permitted frequency deviation, this frequency deviation being in turn the product of the permitted deviation parameter TTT with the expected frequency F_{MOY}, according to the expression: F_{REF-INF}=F_{MOY}*(1−TTT) and F_{REF-SUP}=F_{MOY}*(1+TTT).

During a third step 110, the defects in the TSV vias are detected according to a comparison of the parameters measured with the reference frequency/frequencies. The result B_{RES} of the comparison is generated on 1 bit, for example of value “0” in the event of a detection of a defect and of value “1” if no defect is detected.

In this way, in the embodiment wherein the expected value F_{TH} corresponds to the lowest F_{MIN} of the oscillation frequencies measured, the detection means 22, after receiving from the computer 26 the value of the reference frequency F_{REF}=F_{MIN}*(1+TTT), detect defects in TSV vias once one of the oscillation frequencies measured exceeds this threshold frequency F_{REF}.

In the embodiment wherein the expected value F_{TH} corresponds to the mean F_{MOY} of the oscillation frequencies measured, the detection means 22, after receiving from the computer 26 the reference frequency values F_{REF-INF}=F_{MOY}*(1−TTT) and F_{REF-SUP}=F_{MOY}*(1+TTT) defining the interval [F_{REF-INF}, F_{REF-SUP}], detect defects in the TSV vias once one of the oscillation frequencies measured is outside this interval.

If one or a plurality of defects are detected, i.e. when B_{RES}=0, it is important to be able to locate and repair the TSV vias with defects. To address this need, two so-called diagnostic and development instructions are added to the JTAG instruction. The diagnostic instruction makes it possible to calculate the number of ring oscillators connected to at least one TSV via with a defect and the development instruction makes it possible to test a specific ring oscillator and thus identify the ring oscillators connected to at least one TSV via with a defect or even identify the TSV vias with a defect when each ring oscillator is connected to a single TSV via. These instructions are decoded by the JTAG instruction decoder 30 which interprets and generates instructions to the finite-state machine 28.

The parameters required for generating instruction signals to the finite-state machine 28 such as the counting time T_{C}, the permitted deviation parameter TTT, the identification of the oscillator under test, the choice of the expected value F_{MIN} or F_{MOY}, . . . , are programmable on the JTAG registers 32 by the JTAG tester 34 external to the detection system 10.

The table below illustrates a possible example of distribution of these parameters on a plurality of fields of a JTAG register 32, this register comprising 32 bits:

| 31 . . . 26 | 25 . . . 18 | 17 | 16 | 15 . . . 8 | 7 . . . 4 | 3 . . . 0 |
|---|---|---|---|---|---|---|
| | 70 | 68 | 66 | 64 | 62 | 60 |

The first row of the table shows the bits of the JTAG register 32 assigned to each field. The first 4 bits, from bit 0 to bit 3 of the JTAG register 32, contain a first field 60 comprising identification codes of the various JTAG instructions. The second field 62, from bit 4 to bit 7, contains the value of the permitted deviation parameter TTT. The third field 64, from bit 8 to bit 15, contains an identifier of a ring oscillator selected for the development instruction. The fourth field 66 contains a bit indicating a clock wherein the counting time is to be measured. The fifth field 68 contains a bit for selecting the expected value F_{MIN} or F_{MOY} of one of the two alternative embodiments described above. The sixth field 70 contains the value of the counting time T_{C} on 8 bits. The remainder of the bits of this register, from bit 26 to bit 31, is not used or is used for further optional functions.

In the first example of an embodiment described above, the measuring means 12 comprise ring oscillators 18 and the reference parameter(s) are calculated in relative terms based on the oscillation frequencies of these ring oscillators.

Obviously, alternative embodiments of the measuring means 12 may be envisaged, the reference parameters still being calculated based on the measured parameters.

In a second example of an embodiment of the invention, these measuring means could very well comprise an architecture based on detection amplifiers such as that described in the above-mentioned article by Chen et al. The finite-state machine 28 would enable in this case the sequential selection of the detection amplifiers and the counter 24 would count the number of clock cycles of a reference clock during the discharging time of a TSV via. In this alternative embodiment, unlike the previous embodiment, the counting time T_{C} is variable since it is dependent on the discharging time of the TSV vias. Furthermore, the duration of this discharging time is very short, of the order of 0.5 ns to 3 ns and is not suitable for detecting a sufficient number of clock cycles to be able to detect capacitance variations. Faced with this problem, a possible solution is that of spreading the counting time T_{C}.

It clearly appears that a detection device and method such as those described above make it possible to automatically detect defects in a TSV vias formed in a layer of semiconductor material without the detection of defects being impaired by any variations of the values of the electrical characteristics of the TSV vias and transistors during the circuit production process. By proposing the use of reference parameters calculated in relative terms based on the parameters measured, the precision of defect detection is thus enhanced.

It should further be noted that the invention is not limited to the embodiments described above. Indeed, it will be obvious to those skilled in the art that various modifications may be made to the embodiments described above, in the light of the teaching disclosed herein. In the claims hereinafter, the terms used should not be interpreted as limiting the claims to the embodiments disclosed in the present description, but should be interpreted to include therein any equivalents intended to be covered by the claims due to the wording thereof and which can be envisaged by those skilled in the art by applying general knowledge to the implementation of the teaching disclosed herein.

1. A method for automatic detection of defects in TSV vias formed in a layer of semiconductor material, this detection taking place before stacking this layer with a plurality of other layers of semiconductor material for the design of a multilayer chip integrated circuit, including:
measurement on each of said TSV vias of at least one parameter derived from an electrical characteristic of the TSV vias,
detection of defects in said TSV vias according to a comparison of the parameters measured with at least one reference parameter,
calculating said at least one reference parameter using the measured parameters,
wherein said at least one parameter measured on each of the TSV vias includes an oscillation frequency value derived from a capacitive characteristic of the TSV vias.

2. The method for automatic detection of defects in TSV vias as claimed in claim 1, wherein the calculation of said at least one reference parameter comprises:
the determination, based on the parameters measured, of an expected value of the parameter to be measured on each of said TSV vias, this expected value being considered to be characteristic of a TSV via without defects, and
the calculation of said at least one reference parameter by applying a predefined and programmable permitted deviation parameter relative to this expected value.

3. The method for automatic detection of defects in TSV vias as claimed in claim 2, wherein the measurement on each of said TSV vias of an oscillation frequency derived from a capacitive characteristic of the TSV vias includes the following steps:
connection of a set of ring oscillators to all the TSV vias formed in the layer of semiconductor material, each ring oscillator being connected to at least one TSV via,
sequential selection of each of said ring oscillators,
sequential measurement of an oscillation frequency of each ring oscillator selected.

4. The method for automatic detection of defects in TSV vias as claimed in claim 2, wherein:
the expected value, annotated F_{MIN}, is the lowest of the oscillation frequencies measured,
the permitted deviation parameter, annotated TTT, is expressed as a percentage of the expected value, and
said at least one reference parameter, annotated F_{REF}, is a threshold frequency calculated as follows:
F_{REF}=F_{MIN}·(1+TTT),
defects being detected in said TSV vias once a measured oscillation frequency exceeds this threshold frequency.

5. The method for automatic detection of defects in TSV vias as claimed in claim 2, wherein:
the expected value, annotated F_{MOY}, is the mean of the oscillation frequencies measured,
the permitted deviation parameter, annotated TTT, is expressed as a percentage of the expected value, and
said at least one reference parameter, annotated [F_{REF-INF}, F_{REF-SUP}], consists of the lower and upper limits of a frequency interval calculated as follows:
F_{REF-INF}=F_{MOY}·(1−TTT) and F_{REF-SUP}=F_{MOY}·(1+TTT),
defects being detected in said TSV vias once a measured oscillation frequency is outside this interval.

6. A device for automatic detection of defects in TSV vias formed in a layer of semiconductor material, for a detection taking place before stacking this layer with a plurality of other layers of semiconductor material for the design of a multilayer chip integrated circuit, comprising:
means for measuring on each of said TSV vias at least one parameter derived from an electrical characteristic of the TSV vias,
means for detecting defects in said TSV vias according to a comparison of the parameters measured with at least one reference parameter,
means for calculating said at least one reference parameter based on the parameters measured,
wherein said at least one parameter measured on each of the TSV vias comprises an oscillation frequency value derived from a capacitive characteristic of the TSV vias.

7. The device for automatic detection of defects in TSV vias as claimed in claim 6, wherein the measuring means include a set of ring oscillators connected to all the TSV vias formed in the layer of semiconductor material, each ring oscillator being connected to at least one TSV via.

8. The device for automatic detection of defects in TSV vias as claimed in claim 7, wherein the calculating means include:
a counter of a number of rising edges of an oscillation signal of a ring oscillator selected sequentially for a predefined and programmable counting time, for the sequential supply of an oscillation frequency value,
a computer of at least one expected value of the oscillation frequency to be measured on each of said ring oscillators, this expected value being considered to be characteristic of a ring oscillator connected to at least one TSV via without defects, and of at least one reference frequency by applying a predefined and programmable permitted deviation parameter relative to this expected value.

9. A system for automatic detection of defects in TSV vias, comprising:
a detection device as claimed claim 6, and
a module for controlling access, from an external tester, to the detection device according to the IEEE 1149.1 standard or JTAG standard.
